(19) United States
(12) Patent Application Publication
(10) Pub. No.: US 2025/0183113 A1
(43) Pub. Date: Jun. 5, 2025

(54) SEMICONDUCTOR PACKAGE INCLUDING HEAT SPREADER

(71) Applicant: Samsung Electronics Co., Ltd., Suwon-si (KR)

(72) Inventors: Kang Gyune Lee, Suwon-si (KR); Sang-Won Lee, Suwon-si (KR); Hyeon Hwang, Suwon-si (KR)

(21) Appl. No.: 18/776,668

(22) Filed: Jul. 18, 2024

(30) Foreign Application Priority Data
Dec. 4, 2023 (KR) 10-2023-0173750

(51) Int. Cl. H01L 23/367; H01L 23/00; H01L 23/31; H01L 23/373; H01L 23/498

(52) U.S. Cl. CPC H01L 23/367; H01L 23/3107; H01L 23/3733; H01L 23/49822; H01L 23/49816; H01L 24/16; H01L 24/32; H01L 24/33; H01L 24/73; H01L 2224/16227; H01L 2224/32225; H01L 2224/32245; H01L 2224/33181; H01L 2224/73204; H01L 2224/73253

(57) ABSTRACT

A semiconductor package includes a package substrate, a chip structure on the package substrate, a first mold layer on side surfaces of the chip structure and an upper surface of the package substrate, a heat spreader on the chip structure, and a second mold layer on a side surface of the heat spreader and an upper surface of the first mold layer, where the side surface of the heat spreader includes at least one groove.

### CROSS-REFERENCE TO RELATED APPLICATION

This U.S. non-provisional patent application claims priority under 35 U.S.C. § 119 to Korean Patent Application No. 10-2023-0173750 filed on Dec. 4, 2023, in the Korean Intellectual Property Office, the entire contents of which are hereby incorporated by reference.

### TECHNICAL FIELD

The present disclosure relates to a semiconductor package, and more particularly, relates to a semiconductor package including a heat spreader.

### BACKGROUND

Integrated circuit chips may be provided with a semiconductor package to be suitably applied to circuit boards of electronic products or otherwise combined within an electronic system. In a general semiconductor package, an integrated circuit chip (or a semiconductor chip) may be mounted on a printed circuit board (PCB) and may be electrically connected to the PCB through bonding wirings or bumps. Various researches for improving the reliability and durability of semiconductor packages have been conducted with the development of an electronic industry.

### SUMMARY

An object of the present disclosure is to provide to a semiconductor package with improved reliability.

The problem to be solved by the present disclosure is not limited to the problems mentioned above, and other problems not mentioned will be clearly understood by those skilled in the art from the description below.

A semiconductor package according to some embodiments of the present disclosure includes a package substrate, a chip structure on the package substrate, a first mold layer on side surfaces of the chip structure and an upper surface of the package substrate, a heat spreader on the chip structure, and a second mold layer on a side surface of the heat spreader and an upper surface of the first mold layer, where the side surface of the heat spreader includes at least one groove.

A semiconductor package according to some embodiments of the present disclosure includes a package substrate, a chip structure on the package substrate, a first mold layer on side surfaces of the chip structure and an upper surface of the package substrate, a heat spreader on the chip structure, and a second mold layer on a side surface of the heat spreader and an upper surface of the first mold layer, where the first mold layer includes a first resin layer and first filler particles in the first resin layer, the second mold layer includes a second resin layer and second filler particles in the second resin layer, and a thermal conductivity of the second filler particles is greater than a thermal conductivity of the first filler particles.

A semiconductor package according to some embodiments of the present disclosure includes a package substrate, external connection terminals on a lower surface of the package substrate, a chip structure on the package substrate, a first mold layer on side surfaces of the chip structure and an upper surface of the package substrate, a heat spreader on the chip structure, a thermal interface material layer between the chip structure and the heat spreader, a second mold layer on a side surface of the heat spreader and an upper surface of the first mold layer, and a capping layer on the heat spreader, where the side surface of the heat spreader includes at least one groove, a lower surface of the heat spreader has a first level relative to an upper surface of the package substrate, and a lower surface of the second mold layer has a second level relative to the upper surface of the package substrate that is equal to or lower than the first level.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package according to embodiments of the present disclosure.

FIG. 2 is a cross-sectional view taken along line A-A′ of FIG. 1 according to embodiments of the present disclosure.

FIG. 3 is a perspective view of a heat spreader according to embodiments of the present disclosure.

FIG. 4 is an enlarged view of portion ‘P1’ of FIG. 2.

FIGS. 5A, 5B, 5C, 5D, 5E, 5F, 5G, and 5H are cross-sectional views sequentially illustrating a process of manufacturing the semiconductor package of FIG. 2.

FIG. 6 is a cross-sectional view taken along line A-A′ of FIG. 1 according to embodiments of the present disclosure.

FIG. 7 is an enlarged view of portion ‘P1’ of FIG. 6.

FIGS. 8A, 8B, 8C, and 8D are cross-sectional views illustrating a process of manufacturing the semiconductor package having the cross-section of FIG. 6.

FIG. 9 is a cross-sectional view taken along line A-A′ of FIG. 1 according to embodiments of the present disclosure.

FIG. 10 is a cross-sectional view taken along line A-A′ of FIG. 1 according to embodiments of the present disclosure.

FIG. 11 is a cross-sectional view taken along line A-A′ of FIG. 1 according to embodiments of the present disclosure.

FIG. 12 is a cross-sectional view of a semiconductor package according to embodiments of the present disclosure.

FIG. 13 is a cross-sectional view of a semiconductor package according to embodiments of the present disclosure.

FIG. 14 is a cross-sectional view of a semiconductor package according to embodiments of the present disclosure.

FIG. 15 is a cross-sectional view of a semiconductor package according to embodiments of the present disclosure.

### DETAILED DESCRIPTION

To clarify the present disclosure, parts that are not connected with the description will be omitted, and the same elements or equivalents are referred to by the same reference numerals throughout the specification. In the drawings, the thickness of layers, films, panels, regions, etc., are exaggerated for clarity. Further, since sizes and thicknesses of constituent members shown in the accompanying drawings are arbitrarily given for better understanding and ease of description, the present disclosure is not limited to the illustrated sizes and thicknesses.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, to explain the present disclosure in detail, embodiments according to the present disclosure will be described with reference to the accompanying drawings.

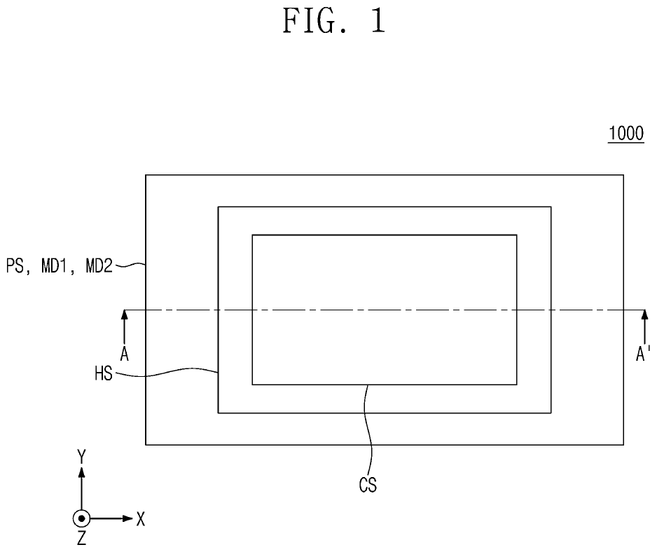

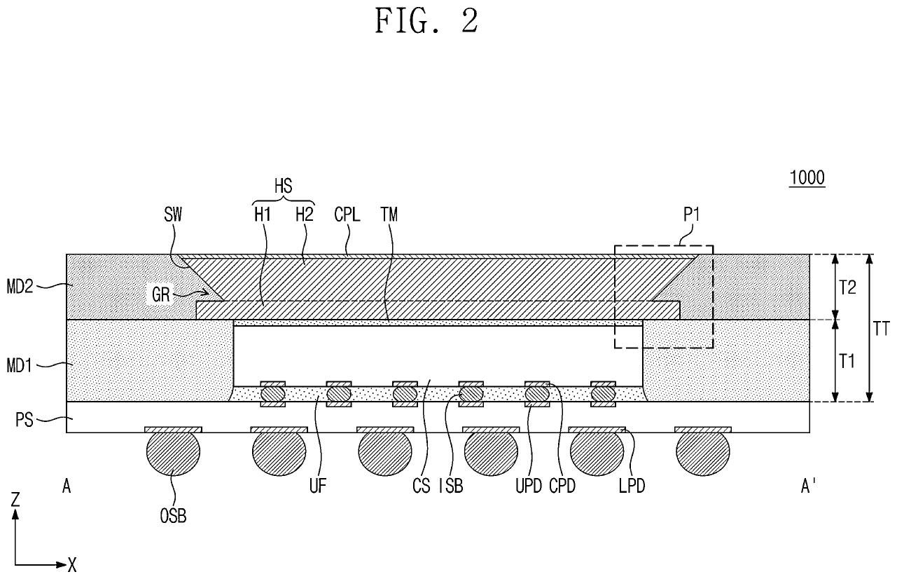

FIG. 1 is a plan view of a semiconductor package according to embodiments of the present disclosure. FIG. 2 is a cross-sectional view taken along line A-A′ of FIG. 1 according to embodiments of the present disclosure.

Referring to FIGS. 1 and 2, a semiconductor package 1000 according to the present embodiments includes a package substrate PS, a chip structure CS, a first mold layer MD1, a heat spreader HS, and a second mold layer MD2. The first mold layer MD1 and the second mold layer MD2 may be formed of epoxy mold compound (EMC). In this specification, the heat spreader HS may be referred to as a heat spreader, heat slug, etc.

The package substrate PS may be, for example, a double-sided or multi-layer printed circuit board. Alternatively, the package substrate PS may be a redistribution substrate. The package substrate PS may include upper substrate conductive patterns UPD disposed on an upper surface thereof and a lower substrate conductive patterns LPD disposed on a lower surface thereof. The upper substrate conductive patterns UPD and the lower substrate conductive patterns LPD may include at least one of copper, aluminum, nickel, and gold. Vias may be disposed in the package substrate PS, and may electrically connect the upper substrate conductive patterns UPD to the lower substrate conductive patterns LPD.

External connection terminals OSB may be bonded to the lower substrate conductive patterns LPD of the package substrate PS. The external connection terminals OSB may be, for example, one of a conductive bump and a solder ball. The external connection terminals OSB may include one of copper and SnAg.

The chip structure CS may be at least one selected from a system large-scale integration (LSI) chip, a logic circuit chip, an image sensor chip (e.g., a CMOS imaging sensor (CIS)), a memory chip (e.g., FLASH memory, DRAM, SRAM, EEPROM, PRAM, MRAM, ReRAM, high bandwidth memory (HBM), or hybrid memory cubic (HMC)), or a microelectromechanical system (MEMS) device. In the present example, one chip structure CS is provided, but more than one chip structure CS may be provided. Chip conductive pads CPD may be disposed on the lower surface of the chip structure CS. The chip conductive pads CPD may include at least one of copper, aluminum, nickel, and gold.

The chip structure CS may be connected to the package substrate PS using internal connection members ISB. The internal connection members ISB may be at least one of a solder ball, a conductive bump, and a conductive pillar. The internal connection members ISB may include at least one of copper, tin, and lead. An underfill layer UF may be interposed between the chip structure CS and the package substrate PS. The underfill layer UF may include a thermosetting resin or a photocurable resin. The underfill layer UF may be a non-conductive film (NCF).

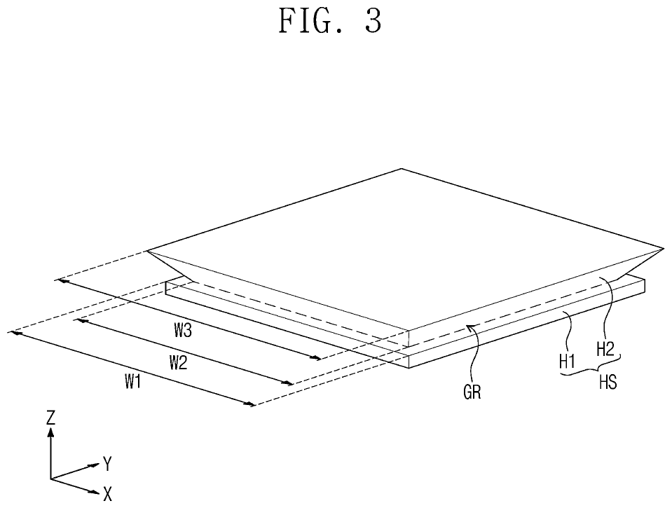

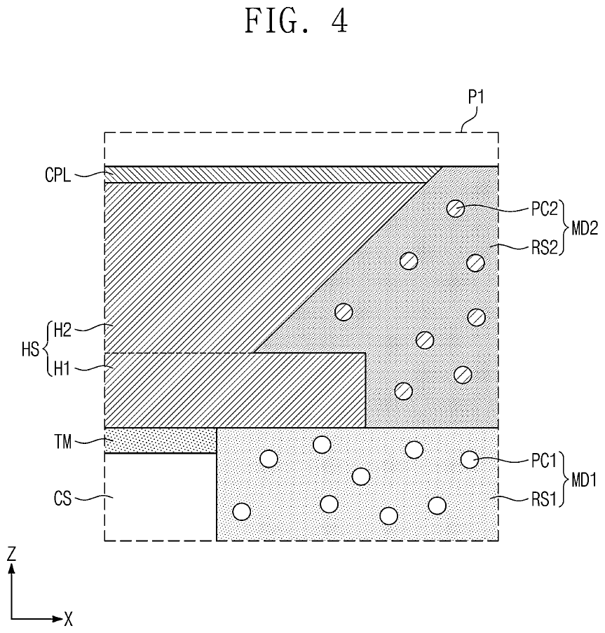

FIG. 3 is a perspective view of a heat spreader according to embodiments of the present disclosure. FIG. 4 is an enlarged view of portion ‘P1’ of FIG. 2.

Referring to FIGS. 2 to 4, the first mold layer MD1 is on and/or covers or overlaps side surfaces of the chip structure CS and an upper surface of the package substrate PS. The first mold layer MD1 may include a first resin layer RS1 and first filler particles PC1 dispersed therein. The first resin layer RS1 may be formed of epoxy or thermosetting resin. The first filler particles PC1 may be formed of, for example, silica. The first mold layer MD1 may have a first thickness T1.

The heat spreader HS is disposed on the chip structure CS. The heat spreader HS may be formed of a thermally conductive metal. For example, the heat spreader HS may be formed of copper. The heat spreader HS may have a groove GR formed on the side surface SW thereof. The heat spreader HS may include a first portion H1 and a second portion H2 formed integrally with each other. The groove GR may be located at an interface between the first portion H1 and the second portion H2. The first portion H1 may have a first width W1 in a first direction X. The first portion H1 may have, for example, a rectangular cross-section. A lower portion of the second portion H2 may have a second width W2 that is smaller than the first width W1. An upper portion of the second portion H2 may have a third width W3 that is larger than the second width W2. A width of the second portion H2 may become wider upward in a third direction Z (e.g., the width of the second portion H2 in a third direction Z increases from a lower portion of the second portion H2 to an upper portion of the second portion H2). The second portion H2 may have, for example, an inverted trapezoidal cross section.

Although not shown, the side surface SW of the heat spreader HS may be covered or overlapped with a diffusion barrier that prevents diffusion of copper. The diffusion barrier may be formed of, for example, Ti, TiN, Ta, or TaN. The diffusion barrier may be interposed between the heat spreader HS and the first mold layer MD1 and between the heat spreader HS and the second mold layer MD2. The diffusion barrier may be interposed between the first portion H1 and the second portion H2 of the heat spreader HS.

A capping layer CPL may be disposed on the heat spreader HS. The capping layer CPL may function to prevent or inhibit copper included in the heat spreader HS from being oxidized or from diffusing to the outside. The capping layer CPL may have a single-layer or multi-layer structure of at least one of steel use stainless (SUS) and titanium.

A thermal interface material layer TM may be interposed between the chip structure CS and the heat spreader HS. The thermal interface material layer TM may also be called an ‘adhesive layer’. The thermal interface material layer TM may further include filler particles dispersed in the thermosetting resin layer. The filler particles may include at least one of silica, alumina, zinc oxide, and nitrogen boride. The thermal interface material layer TM may serve to transfer heat generated from the chip structure CS to the heat spreader HS and quickly dissipate the heat to the outside. The thermal interface material layer TM may serve as a buffer to relieve physical stress between the chip structure CS and the heat spreader HS. An upper surface of the thermal interface material layer TM may be coplanar with an upper surface of the first mold layer MD1.

A second mold layer MD2 is disposed on the first mold layer MD1. A lower surface of the second mold layer MD2 may be positioned at the same level as a lower surface of the heat spreader HS (e.g., the lower surface of the second mold layer MD2 and the lower surface of the heat spreader HS are coplanar). A thermal conductivity of the second mold layer MD2 may be greater than a thermal conductivity of the first mold layer MD1. The second mold layer MD2 may include a second resin layer RS2 and second filler particles PC2 dispersed therein. The second resin layer RS2 may be the same as or different from the first resin layer RS1. For example, the second resin layer RS2 may be formed of epoxy or thermosetting resin. The second filler particles PC2 may be different from the first filler particles PC1. For example, a strength of the second filler particles PC2 may be different from a strength of the first filler particles PC1. A thermal conductivity of the second filler particles PC2 may be greater than a thermal conductivity of the first filler particles PC1 included in the first mold layer MD1. The second filler particles PC2 may include, for example, at least one of aluminum, silver, tin, tungsten, copper, zinc, and titanium. The second filler particles PC2 may include, for example, at least one of alumina, titania, and zinc oxide. In the present disclosure, as the second filler particles PC2 are different from the first filler particles PC1, the second mold layer MD2 may be adjusted to have different physical properties from the first mold layer MD1. As a result, a warpage problem of the semiconductor package 1000 may be improved and reliability thereof may be improved.

An upper surface of the capping layer CPL is coplanar with an upper surface of the second mold layer MD2. The second mold layer MD2 may have a second thickness T2 that is smaller than the first thickness T1 of the first mold layer MD1. The second thickness T2 is 1/10 to ¼ of the total thickness TT of the first and second mold layers MD1 and MD2, which corresponds to the sum of the first thickness T1 and the second thickness T2.

The semiconductor package 1000 according to the present disclosure may include a heat spreader HS adjacent to the upper surface of the chip structure CS and may effectively radiate heat generated from the chip structure CS to the outside. Additionally, the second portion H2 of the heat spreader HS may have a width that increases from a lower portion to an upper portion of the second portion H2, and thus it may be more effective in dissipating heat. In addition, the second filler particles PC2 included in the second mold layer MD2 have a thermal conductivity greater than that of the first filler particles PC1 included in the first mold layer MD1, and thus heat generated from the chip structure CS may be effectively radiated to the outside. In addition, the upper surface of the chip structure CS may be covered or overlapped by the heat spreader HS and may not be exposed to the outside, thereby protecting or inhibiting the chip structure CS from external shock.

A portion of the second mold layer MD2 may be inserted into the groove GR of the heat spreader HS. As a result, it is difficult for the heat spreader HS to be separated from the second mold layer MD2. Accordingly, adhesion between the heat spreader HS and the second mold layer MD2 may be improved, and interface separation therebetween may be prevented or inhibited, thereby improving reliability of the semiconductor package 1000.

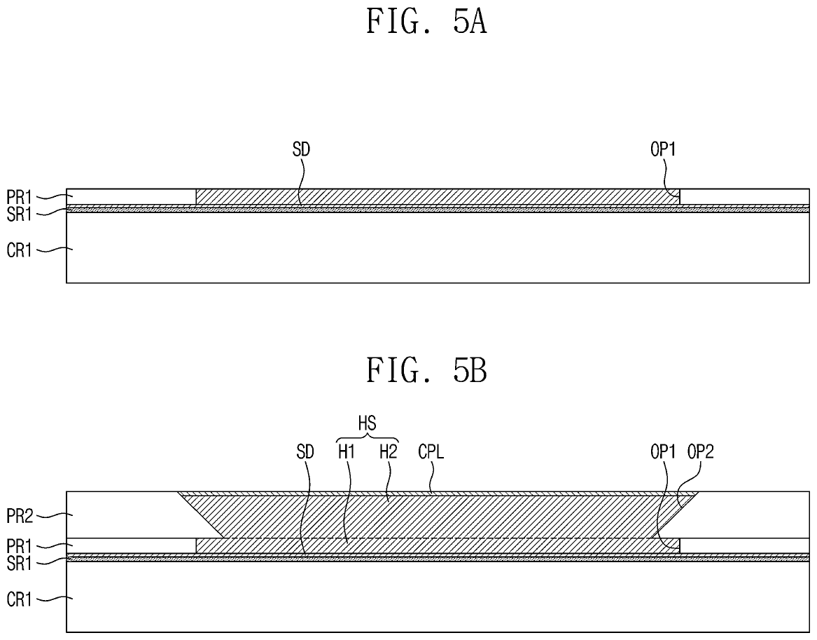

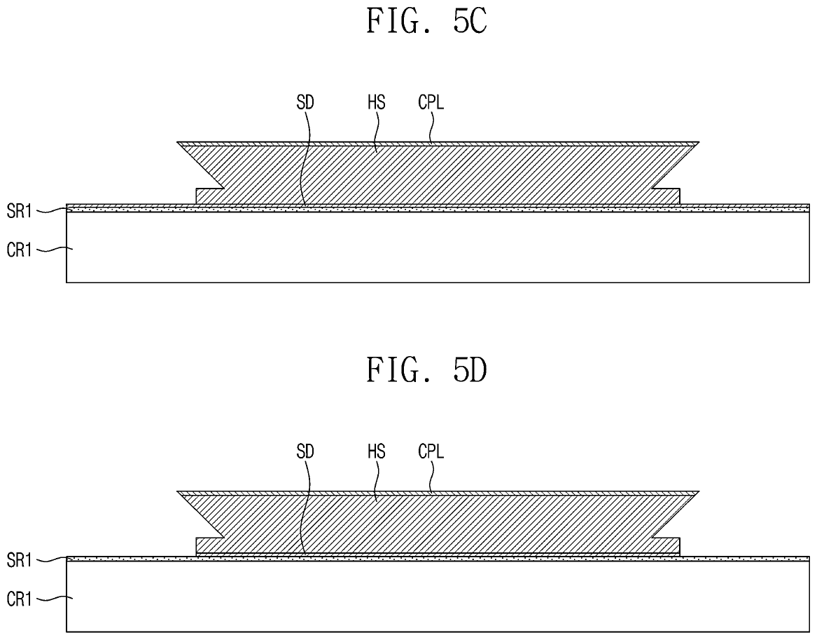

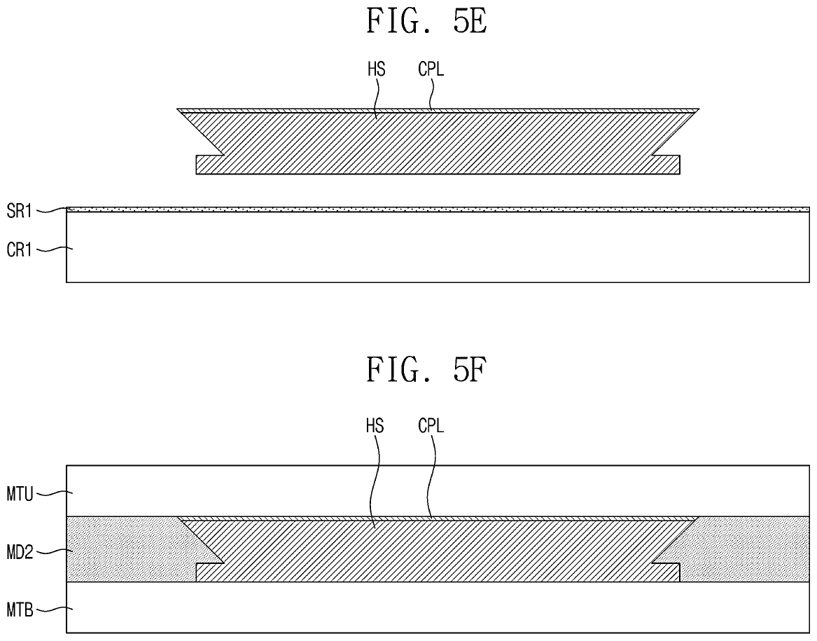

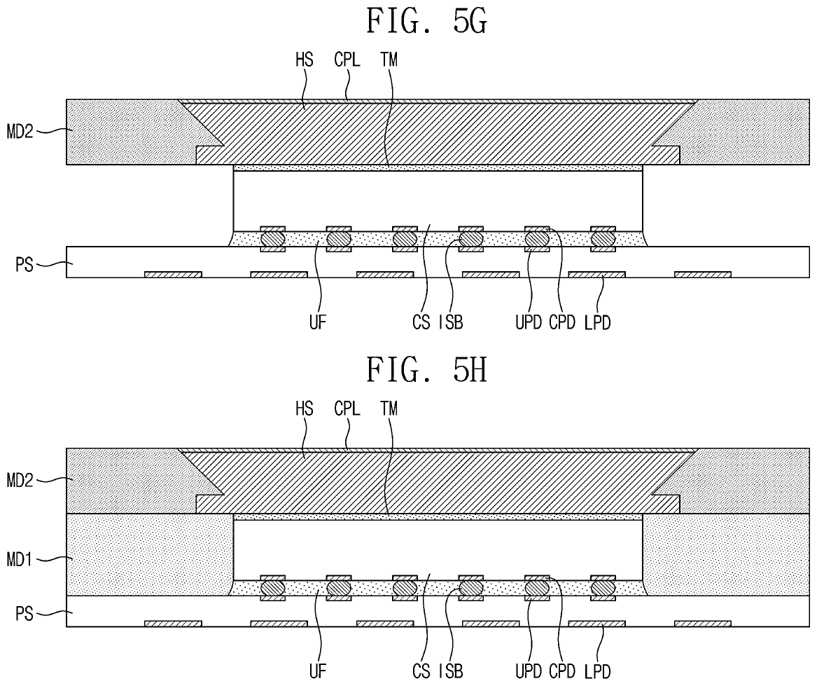

FIGS. 5A to 5H are cross-sectional views sequentially illustrating a process of manufacturing the semiconductor package of FIG. 2.

Referring to FIG. 5A, a sacrificial layer SR1 is formed on a carrier substrate CR1. The sacrificial layer SR1 may be an adhesive tape or a photodegradable adhesive layer. A seed layer SD is formed on the sacrificial layer SR1. The seed layer SD may be formed of copper, for example. The seed layer SD may be formed through a sputtering process or a physical vapor deposition (PVD) process. A first mask pattern PR1 is formed on the seed layer SD. The first mask pattern PR1 may be, for example, a photoresist pattern. The first mask pattern PR1 may include a first opening OP1 that exposes the seed layer SD and defines a shape of the first portion H1 of the heat spreader HS. A first plating process is performed to form a first portion H1 of the heat spreader HS that fills the first opening OP1.

Referring to FIG. 5B, a second mask pattern PR2 is formed on the first mask pattern PR1 and the first portion H1. The second mask pattern PR2 may include a second opening OP2 that exposes the first portion H1 and defines a shape of the second portion H2. A second plating process is performed to form the second portion H2 of the heat spreader HS in the second opening OP2. Then, a third plating process or deposition process is performed to form a capping layer CPL on the second portion H2 of the heat spreader HS.

Referring to FIG. 5C, the second mask pattern PR2 and the first mask pattern PR1 are removed to expose the seed layer SD. When the second mask pattern PR2 and the first mask pattern PR1 are formed as a photoresist pattern, an ashing process may be performed to remove the second mask pattern PR2 and the first mask pattern PR1.

Referring to FIG. 5D, the seed layer SD next or adjacent to the heat spreader HS is removed to expose the sacrificial layer SR1. There may be no interface between the seed layer SD and the heat spreader HS. The seed layer SD under the heat spreader HS may form a portion of the first portion H1 of the heat spreader HS.

Referring to FIG. 5E, the heat spreader HS is separated from the sacrificial layer SR1 and the carrier substrate CR1. As a result, the heat spreader HS and the capping layer CPL may be manufactured.

Referring to FIG. 5F, the heat spreader HS with the capping layer CPL formed on the upper surface is placed between a lower mold frame MTB and an upper mold frame MTU, and the first molding process is performed. That is, a second resin liquid in which the second filler particles PC2 of FIG. 4 are dispersed is supplied between the lower mold frame MTB and the upper mold frame MTU to fill or be in a space therebetween, and then a heat curing process is performed, thereby forming a second mold layer MD2.

Referring to FIG. 5G, the second mold layer MD2 into which the heat spreader HS and the capping layer CPL are inserted is separated from the lower mold frame MTB and the upper mold frame MTU. A chip structure CS is mounted on a package substrate PS using internal connection members ISB. An underfill layer UF is formed between the chip structure CS and the package substrate PS. A thermal interface material layer TM is formed on the chip structure CS. The heat spreader HS inserted into the second mold layer MD2 is attached to a thermal interface material layer TM.

Referring to FIG. 5H, the structure of FIG. 5G is placed between the lower mold frame MTB and the upper mold frame MTU of FIG. 5F and a secondary molding process is performed. That is, a first resin liquid in which the first filler particles PC1 of FIG. 4 are dispersed is supplied between the second mold layer MD2 and the package substrate PS to fill or be in a space therebetween, and then a thermal curing process is performed, thereby forming a first mold layer MD1.

Subsequently, referring to FIG. 2, external connection terminals OSB are bonded to a lower surface of the package substrate PS. Additionally, a singulation process may be performed to separate each individual semiconductor package.

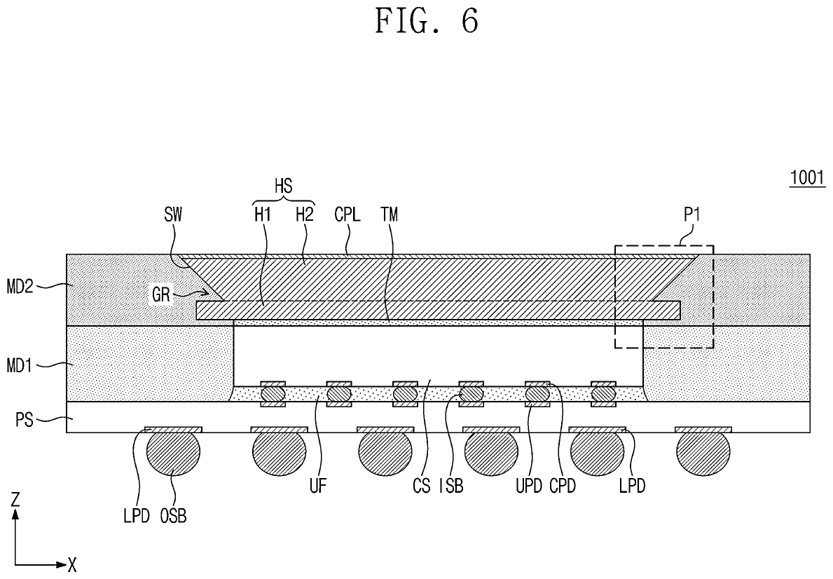

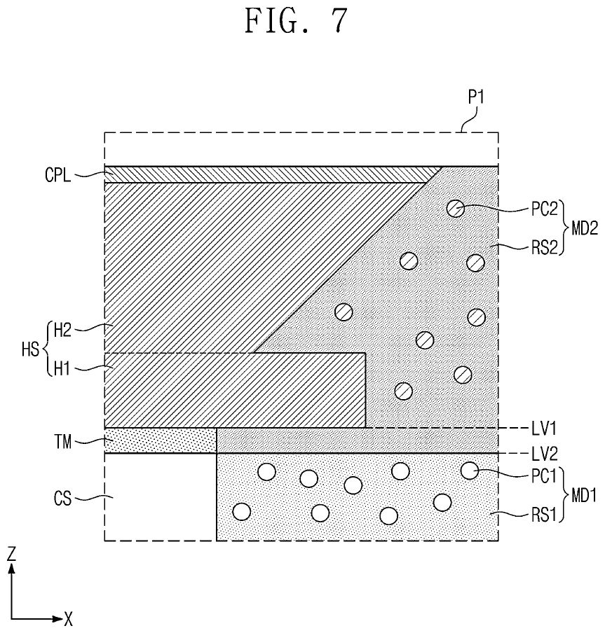

FIG. 6 is a cross-sectional view taken along line A-A′ of FIG. 1 according to embodiments of the present disclosure. FIG. 7 is an enlarged view of portion ‘P1’ of FIG. 6.

Referring to FIGS. 6 and 7, in a semiconductor package 1001 according to the present example, a portion of a second mold layer MD2 may be interposed between the heat spreader HS and the first mold layer MD1 to be in contact with a side surface of a thermal interface material layer TM. A lower surface HS_B of the heat spreader HS may have a first level LV1. A lower surface MD2_B of the second mold layer MD2 may have a second level LV2 lower than the first level LV1 (e.g., a distance between the package substrate PS and the second level LV2 is less than a distance between the package substrate PS and the first level LV1). Other structures may be the same/similar to those described above.

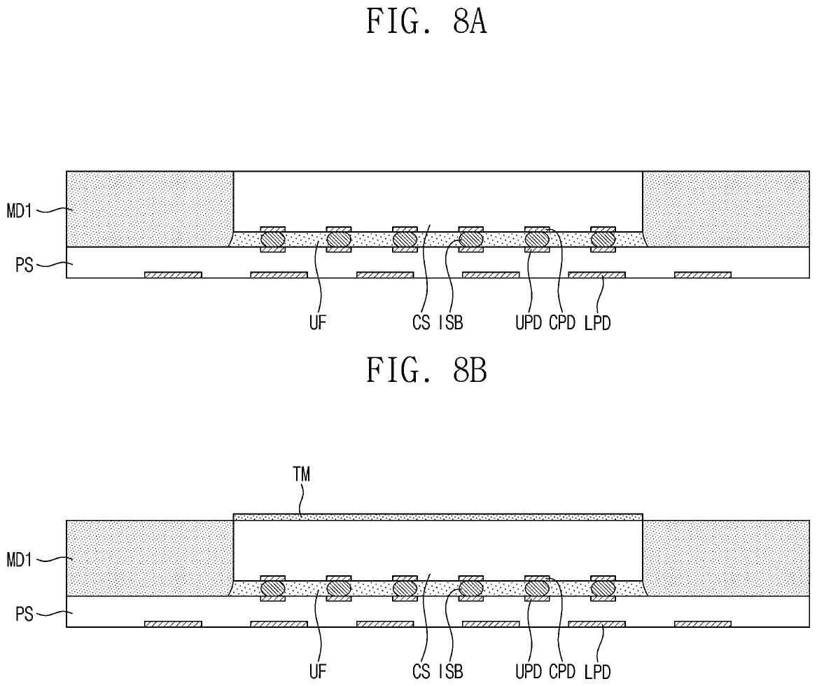

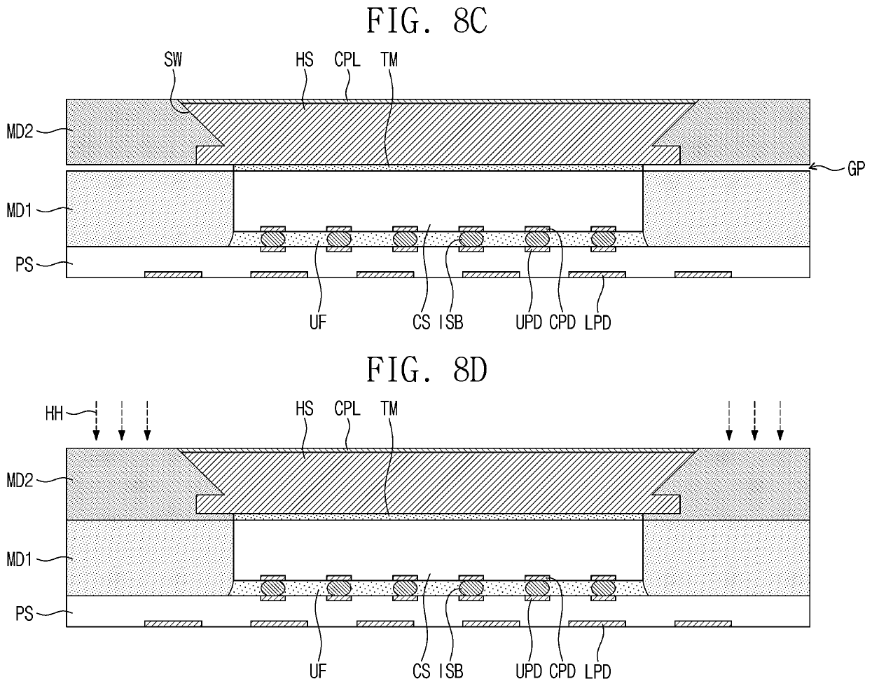

FIGS. 8A to 8D are cross-sectional views illustrating a process of manufacturing the semiconductor package having the cross-section of FIG. 6.

Referring to FIG. 8A, a chip structure CS is mounted on a package substrate PS using internal connection members ISB. An underfill layer UF is formed between the chip structure CS and the package substrate PS. A first mold layer MD1 is formed on and/or to cover or overlap a side surface of the chip structure CS and an upper surface of the package substrate PS.

Referring to FIG. 8B, a thermal interface material layer TM is formed on the upper surface of the chip structure CS.

Referring to FIG. 8C, a heat spreader HS inserted into the second mold layer MD2 manufactured through the process of FIGS. 5A to 5E is attached to the thermal interface material layer TM. In this case, an epoxy state of the second resin layer RS2 included in the second mold layer MD2 may be in a “B” stage, which is an uncured state or a partially cured state. An empty space GP may exist between the second mold layer MD2 and the first mold layer MD1.

Referring to FIG. 8D, heat (indicated by dashed arrows HH) is applied to the second mold layer MD2 to cure the second mold layer MD2.

Referring to FIG. 5H, the structure of FIG. 5G is placed between the lower mold frame MTB and the upper mold frame MTU of FIG. 5F and a secondary molding process is performed. That is, a first resin liquid in which the first filler particles PC1 of FIG. 4 are dispersed is supplied between the second mold layer MD2 and the package substrate PS to fill or be in a space therebetween, and then a thermal curing process is performed to cure the second mold layer MD. In this case, a portion of the second mold layer MD2 may fill or be in an empty space GP. Accordingly, the second mold layer MD2 may be in contact with the first mold layer MD1 and may fill or be in a space between the heat spreader HS and the first mold layer MD1. Accordingly, the semiconductor package 1001 of FIG. 6 may be manufactured.

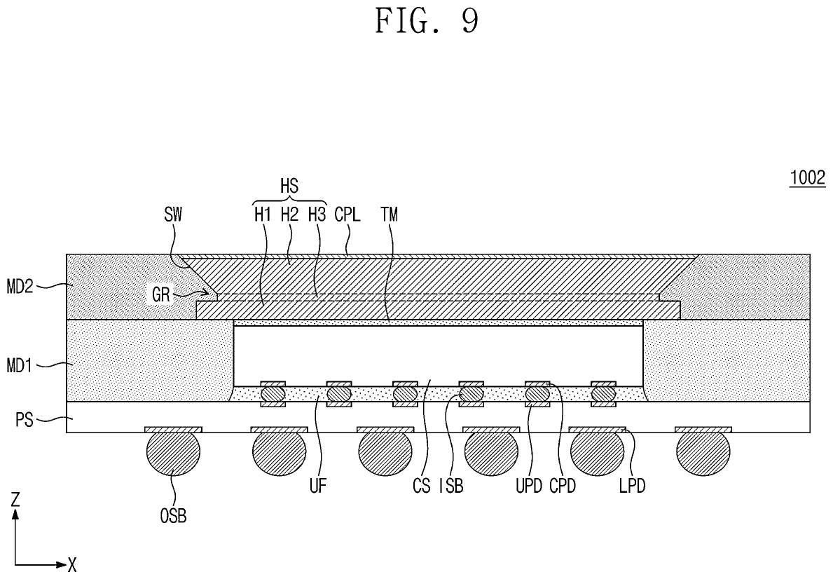

FIG. 9 is a cross-sectional view taken along line A-A′ of FIG. 1 according to embodiments of the present disclosure.

Referring to FIG. 9, in a semiconductor package 1002 according to this example, a heat spreader HS may further include a third portion H3 between the first portion H1 and the second portion H2 described in FIG. 2. The third portion H3 may have a rectangular cross-section and a width equal to a width of a lower portion of the second portion H2. A groove GR may correspond to a side surface of the third portion H3. Other structures may be the same/similar to those described above.

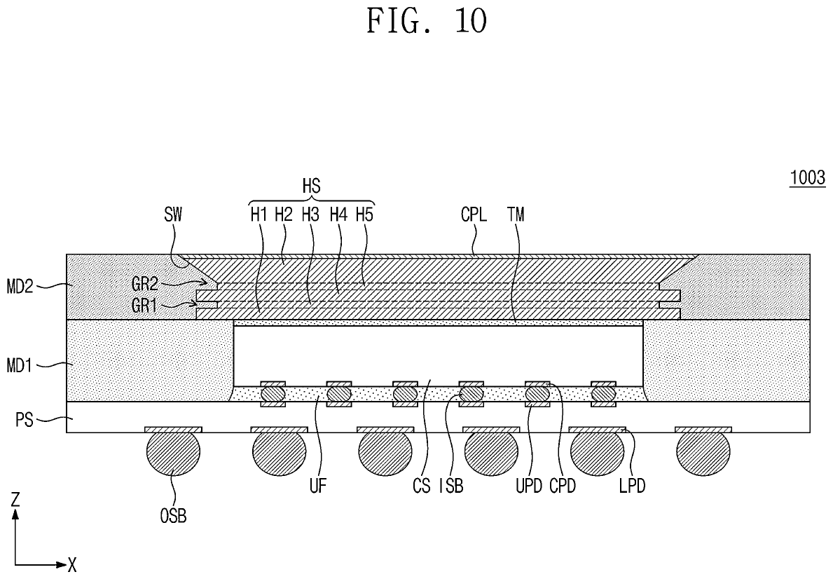

FIG. 10 is a cross-sectional view taken along line A-A′ of FIG. 1 according to embodiments of the present disclosure.

Referring to FIG. 10, in a semiconductor package 1003 according to the present example, a heat spreader HS may further include a fourth portion H4 and a fifth portion H5 in the structure of FIG. 9. The fourth portion H4 and the fifth portion H5 may each have a rectangular cross-section. The fourth portion H4 may disposed between the third portion H3 and the second portion H2 and may have the same width as the first portion H1. The fifth portion H5 may be disposed between the fourth portion H4 and the second portion H2 and may have the same width as the third portion H3. A side surface SW of the heat spreader HS may have two grooves GR1 and GR2. The first groove GR1 may correspond to a side surface of the third portion H3. The second groove GR2 may correspond to a side surface of the fifth portion H5. The second mold layer MD2 may be inserted between the first groove GR1 and the second groove GR2. In this example, although two grooves GR1 and GR2 are disclosed, the number of grooves may be three or more, but not limited thereto. Other structures may be the same/similar to those described above.

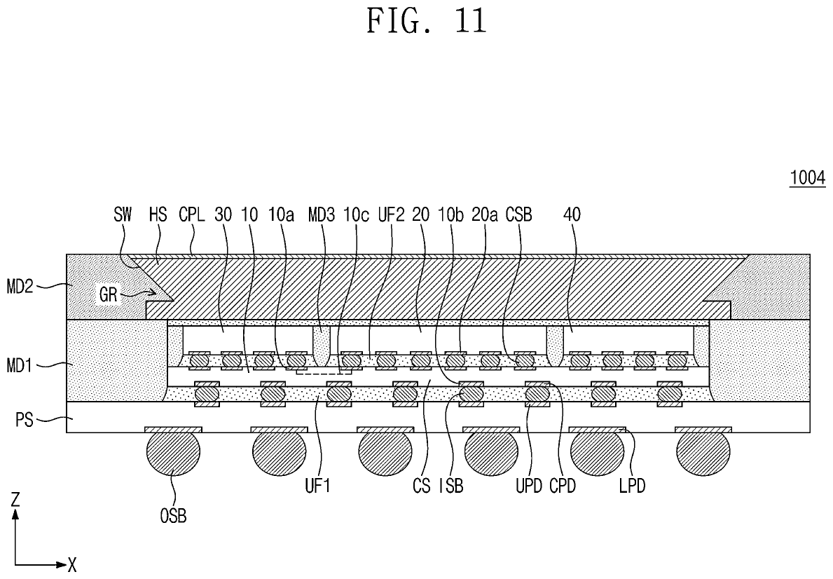

FIG. 11 is a cross-sectional view taken along line A-A′ of FIG. 1 according to embodiments of the present disclosure.

Referring to FIG. 11, in a semiconductor package 1004 according to this example, a chip structure CS may include an interposer substrate 10, a first semiconductor chip 20, a second semiconductor chip 30, and a third semiconductor chip 40, and a third mold layer MD3. The first semiconductor chip 20 may be a large scale integration (LSI) chip, a logic circuit chip, a processor chip, or an application-specific integrated circuit (ASIC) chip. The second semiconductor chip 30 and the third semiconductor chip 40 may be memory chips, such as a high bandwidth memory (HBM) chip or a hybrid memory cubic (HMC) chip. Connection wirings 10c and upper conduction pads 10a are disposed in the interposer substrate 10 and connect the second semiconductor chip 30 and the third semiconductor chip 40 to the first semiconductor chip 20 via chip conduction pads 20a. As a result, signal transmission speed between the second semiconductor chip 30 and the third semiconductor chip 40, and the first semiconductor chip 20 may be improved. Lower conduction pads 10b of the interposer substrate 10 connect the package substrate PS to the interposer substrate 10. The third mold layer MD3 may be on and/or cover or overlap side surfaces of the first semiconductor chip 20, the second semiconductor chip 30, and the third semiconductor chip 40 while exposing upper surfaces thereof. Other structures may be the same/similar to those described with reference to FIGS. 2 to 10.

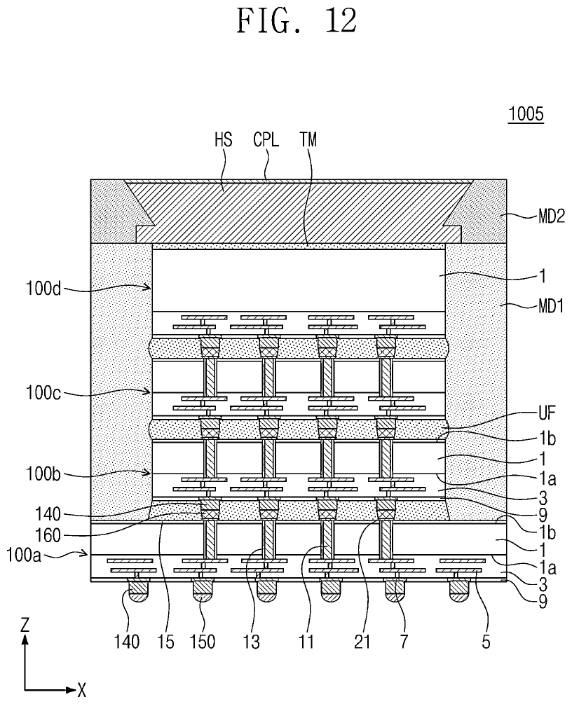

FIG. 12 is a cross-sectional view of a semiconductor package according to embodiments of the present disclosure.

Referring to FIG. 12, a semiconductor package 1005 according to this example includes first to fourth semiconductor chips 100a to 100d sequentially stacked and a first mold layer MD1 on and/or covering or overlapping the first to fourth semiconductor chips 100a to 100d. A width of the first semiconductor chip 100a may be wider than the second to fourth semiconductor chips 100b, 100c, and 100d. The first semiconductor chip 100a may be a different type of chip from the second to fourth semiconductor chips 100b, 100c, and 100d. For example, the first semiconductor chip 100a may be a logic circuit chip. The second to fourth semiconductor chips 100b, 100c, and 100d may be the same memory chip (e.g., DRAM chip). In this example, a structure in which one logic circuit chip and three memory chips are stacked is disclosed, but the number of stacked logic circuit chips and memory chips is not limited thereto and may be variously changed. The semiconductor package 1005 may have a high bandwidth memory (HBM) chip structure.

Each of the first to fourth semiconductor chips 100a to 100d may include a semiconductor substrate 1, an interlayer insulating layer 3, wirings 5, a first conductive pad 7, a conductive bump 140, a first passivation layer 9, and a second passivation layer 15. The semiconductor substrate 1 may include an upper surface 1a and a back surface 1b that face each other. The interlayer insulating layer 3 may be disposed on the upper surface 1a of the substrate. Transistors (not shown) and multi-layered wiring 5 may be disposed in the interlayer insulating layer 3. The interlayer insulating layer 3 may be covered with or overlapped by the first passivation layer 9. The first conductive pads 7 may be disposed under the interlayer insulating layer 3. The conductive bumps 140 may be respectively bonded to the first conductive pads 7. A solder layer 150 may be bonded under the conductive bumps 140 of the first semiconductor chip 100a. The back surface 1b of the substrate may be covered with or overlapped by the second passivation layer 15.

The first to third semiconductor chips 100a to 100c may each further include a through via 11 and a through insulating layer 13. In each of the first to third semiconductor chips 100a to 100c, the through via 11 may penetrate or extend into a portion of the second passivation layer 15, the semiconductor substrate 1, and the interlayer insulating layer 3. The through insulating layer 13 may be interposed between the through via 11 and the semiconductor substrate 1. An upper surface of the through via 11 may be in contact with the second conductive pad 21. A lower surface of the through via 11 may be in contact with one of the wirings 5.

The fourth semiconductor chip 100d may exclude the through via 11 and the through insulating layer 13. A thickness of the semiconductor substrate 1 included in the fourth semiconductor chip 100d may be less than a thickness of the semiconductor substrate 1 included in the second semiconductor chip 100b or the third semiconductor chip 100c.

The first to fourth semiconductor chips 100a, 100b, 100c, and 100d may be connected to each other by internal connection members 160. Each of the internal connection members 160 may connect the second conductive pad 21 of the respective semiconductor chip to the conductive bump 140 of the semiconductor chip disposed directly above the respective semiconductor chip. An underfill layer UF may be interposed between the first to fourth semiconductor chips 100a, 100b, 100c, and 100d.

The semiconductor substrates 1 may be a semiconductor substrate, a silicon single crystal substrate, or a silicon on insulator (SOI) substrate. The interlayer insulating layers 3 may include at least one single layer or multilayer selected from a silicon oxide layer, a silicon nitride layer, a silicon oxynitride layer, and a porous insulating layer.

Each of the first conductive pads 7, the second conductive pads 21, the conductive bumps 140, the solder layer 150, the wirings 5, and the through vias 11 may include a conductive material, such as a metal. The solder layer 150 may include SnAg, for example. The wirings 5 may include a same or different conductive material and may include at least one of, for example, copper, tungsten, aluminum, ruthenium, titanium, tantalum, titanium nitride, and tantalum nitride. The through vias 11 may include tungsten, for example.

A thermal interface material layer TM may be disposed on the fourth semiconductor chip 100d. A heat spreader HS covered with or overlapped by a capping layer CPL may be bonded on the thermal interface material layer TM. A second mold layer MD2 may be disposed on the first mold layer MD1. Other structures may be the same/similar to those described above.

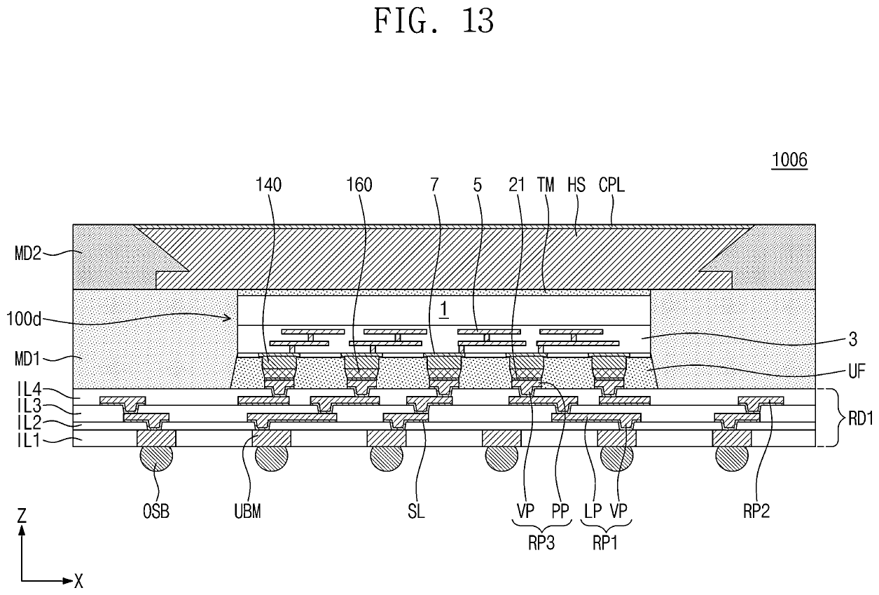

FIG. 13 is a cross-sectional view of a semiconductor package according to embodiments of the present disclosure.

Referring to FIG. 13, a semiconductor package 1006 according to this example includes a first redistribution substrate RD1, a fourth semiconductor chip 100d mounted thereon, a first mold layer MD1 on and/or covering or overlapping the first redistribution substrate RD1 and the fourth semiconductor chip 100d, and a second mold layer MD2 and a heat spreader HS that are on and/or cover or overlap the first mold layer MD1, the first redistribution substrate RD1, and the fourth semiconductor chip 100d. The first redistribution substrate RD1 may correspond to the package substrate PS of FIG. 2. The fourth semiconductor chip 100d may correspond to the chip structure CS of FIG. 2.

The first redistribution substrate RD1 may include first to fourth insulating layers IL1 to IL4 that are sequentially stacked. Each of the first to fourth insulating layers IL1 to IL4 may include a photo imageable dielectric (PID). An under bump UBM may be disposed in the first insulating layer IL1. The first redistribution pattern RP1 is disposed between the third insulating layer IL3 and the second insulating layer IL2. The second redistribution pattern RP2 is disposed between the fourth insulating layer IL4 and the third insulating layer IL3. The third redistribution pattern RP3 is disposed on the fourth insulating layer IL4. Lower surfaces of the first to fourth redistribution patterns RP1 to RP4 may be covered with or overlapped by a barrier/seed layer SL.

The first to third redistribution patterns RP1 to RP3 may include a via portion VP, a line portion LP, and a pad portion PP, respectively. The via portion VP may have a width that narrows or decreases downward in the Z direction and/or as it approaches a lower surface of the respective insulating layer.

A second conductive pad 21 is disposed on the pad portion PP of the third redistribution pattern RP3. The fourth semiconductor chip 100d includes conductive bumps 140. The internal connection member 160 may connect the conductive bump 140 of the fourth semiconductor chip 100d to the second conductive pad 21 of the first redistribution substrate RD1. The second conductive pad 21 may include nickel, for example.

An underfill layer UF may be interposed between the first redistribution substrate RD1 and the fourth semiconductor chip 100d. The underfill layer UF may be in contact with a sidewall of the third redistribution pattern RP3 and an upper surface of the fourth insulating layer IL4.

A thermal interface material layer TM may be disposed on the fourth semiconductor chip 100d. A heat spreader HS covered with or overlapped by a capping layer CPL may be bonded on the thermal interface material layer TM. A second mold layer MD2 may be disposed on the first mold layer MD1. Other structures may be the same/similar to those described with reference to FIGS. 1 to 4.

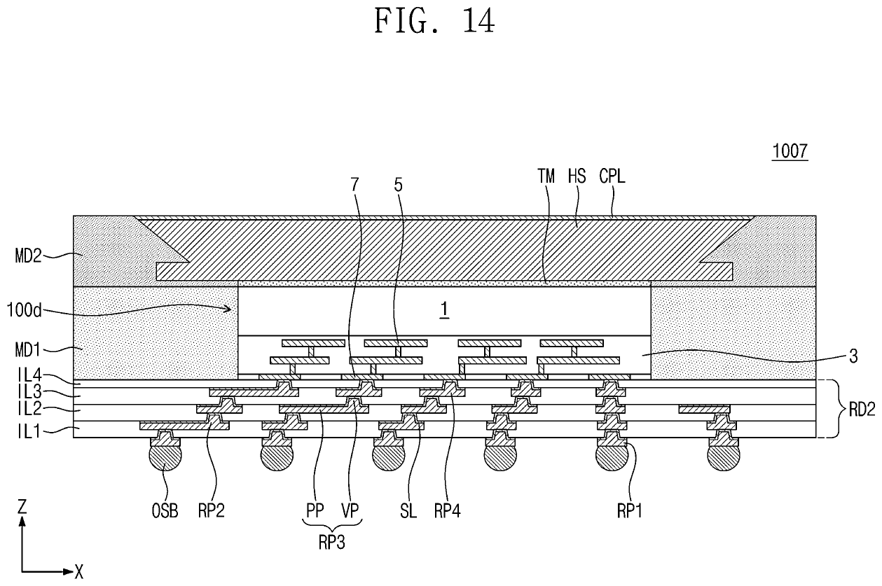

FIG. 14 is a cross-sectional view of a semiconductor package according to embodiments of the present disclosure.

Referring to FIG. 14, a semiconductor package 1007 according to this example includes a second redistribution substrate RD2, a fourth semiconductor chip 100d mounted thereon, a first mold layer MD1 on and/or covering or overlapping the first redistribution substrate RD1 and the fourth semiconductor chip 100d, and a second mold layer MD2 and a heat spreader HS on and/or covering or overlapping the first mold layer MD1, the first redistribution substrate RD1, and the fourth semiconductor chip 100d. The second redistribution substrate RD2 may correspond to the package substrate PS of FIG. 2. The fourth semiconductor chip 100d may correspond to the chip structure CS of FIG. 2.

The second redistribution substrate RD2 may include first to fourth insulating layers IL1 to IL4 that are sequentially stacked. The first to fourth insulating layers IL1 to IL4 may each include a photo imageable dielectric (PID). The first redistribution pattern RP1 is disposed below the first insulating layer IL1 and penetrates or extends into the first insulating layer IL1. The second redistribution pattern RP2 is disposed between the first insulating layer IL1 and the second insulating layer IL2. The third redistribution pattern RP3 is disposed between the second insulating layer IL2 and the third insulating layer IL3. The fourth redistribution pattern RP4 is disposed between the third insulating layer IL3 and the fourth insulating layer IL4. Upper surfaces of the first to fourth redistribution patterns RP1 to RP4 may be covered with or overlapped by a barrier/seed layer SL.

The first to fourth redistribution patterns RP1 to RP4 may include a via portion VP, a line portion LP, and a pad portion PP, respectively. The via portion VP may have a width that narrows or decreases upward in the Z direction and/or as it approaches an upper surface of the respective insulating layer.

The second redistribution substrate RD2 is in direct contact with the fourth semiconductor chip 100d. The first conductive pad 7 of the fourth semiconductor chip 100d may be in direct contact with the via portion VP of the fourth redistribution pattern RP4.

A thermal interface material layer TM may be disposed on the fourth semiconductor chip 100d. A heat spreader HS covered with or overlapped by a capping layer CPL may be bonded on the thermal interface material layer TM. A second mold layer MD2 may be disposed on the first mold layer MD1. Other structures may be the same/similar to those described with reference to FIGS. 6 and 7.

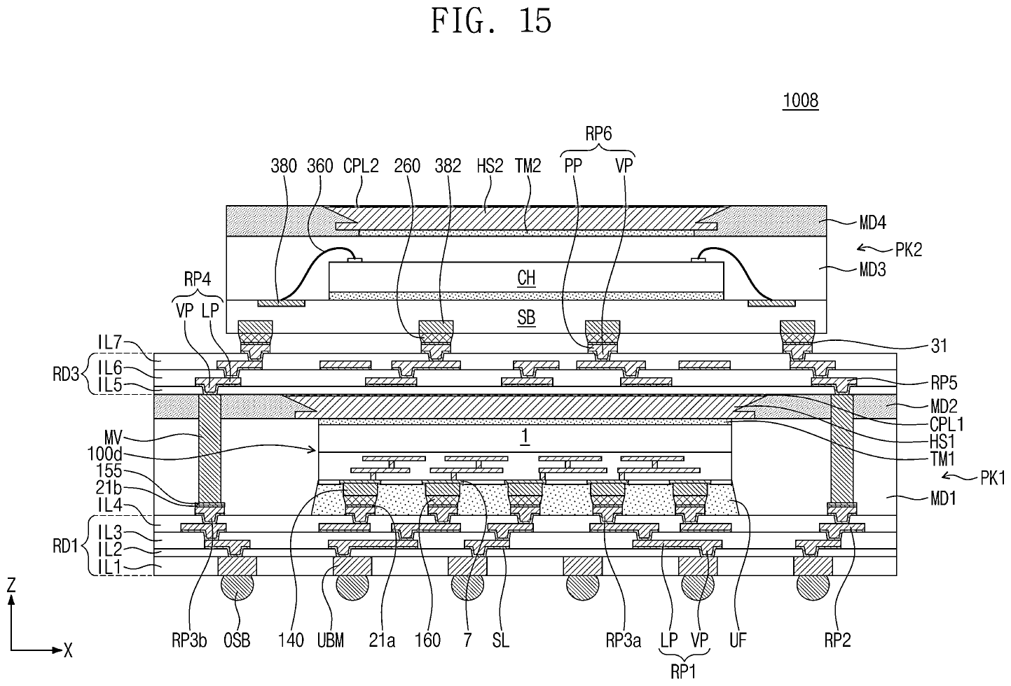

FIG. 15 is a cross-sectional view of a semiconductor package according to embodiments of the present disclosure.

Referring to FIG. 15, a semiconductor package 1008 according to this example includes a first sub-semiconductor package PK1 and a second sub-semiconductor package PK2 stacked thereon. The first sub-semiconductor package PK1 may further include a third redistribution substrate RD3 disposed in the structure of the semiconductor package 1006 of FIG. 13, and a mold via MV connecting the first redistribution substrate RD1 and the third redistribution substrate RD3.

In detail, the first redistribution substrate RD1 may have the same/similar structure as described with reference to FIG. 13. The first redistribution substrate RD1 may include third central redistribution patterns RP3a disposed at a center of the first redistribution substrate RD1, and third edge redistribution patterns RP3b disposed at an edge of the first redistribution substrate RD1. Second central conductive pads 21a may be respectively disposed on the third central redistribution patterns RP3a. Second edge conductive pads 21b may be respectively disposed on the third edge redistribution patterns RP3b. Wetting layers 155 may be respectively disposed on the second edge conductive pads 21b.

A fourth semiconductor chip 100d may be mounted on the first redistribution substrate RD1. A first internal connection members 160 may connect the second central conductive pads 21a of the first redistribution substrate RD1 and the conductive bumps 140 of the fourth semiconductor chip 100d. Another portion of the third redistribution patterns RP3 may be disposed next to the fourth semiconductor chip 100d. The fourth semiconductor chip 100d and the second redistribution substrate RD2 are covered with or overlapped by the first mold layer MD1. The mold via MV may penetrate or extend into the first mold layer MD1 and the second mold layer MD2 and may be in contact with the wetting layers 155 on the second edge conductive pads 21b. The mold via MV may include copper, for example. The second central conductive pads 21a and the second edge conductive pads 21b may include nickel, for example. The wetting layer 155 may include, for example, gold (Au).

A first thermal interface material layer TM1 is disposed on the fourth semiconductor chip 100d. The first heat spreader HS1 is disposed on the first thermal interface material layer TM1. A first capping layer CPL1 is disposed on a first heat spreader HS1. The second mold layer MD2 is disposed on a side surface of the first heat spreader HS1. The first mold layer MD1, the second mold layer MD2, the first thermal interface material layer TM1, the first heat spreader HS1, and the first capping layer CPL1 may be the same/similar to what was described with reference to FIGS. 1 to 10.

The third redistribution substrate RD3 is disposed on the second mold layer MD2 and the first heat spreader HS1. The third redistribution substrate RD3 includes fifth to seventh insulating layers IL5 to IL7 that are sequentially stacked. Each of the fifth to seventh insulating layers IL5 to IL7 may include a photo imageable dielectric (PID) layer. A fourth redistribution pattern RP4 is interposed between the fifth insulating layer IL5 and the sixth insulating layer IL6. The fourth redistribution pattern RP4 may be connected to the mold via MV. The fifth redistribution pattern RP5 is interposed between the sixth insulating layer IL6 and the seventh insulating layer IL7. Each of the fourth redistribution pattern RP4 and the fifth redistribution pattern RP5 may have a via portion VP and a line portion LP. The sixth redistribution pattern RP6 may be disposed on the seventh insulating layer IL7. Lower surfaces of the fourth to sixth redistribution patterns RP4 to RP6 may be covered with or overlapped by a barrier/seed layer SL. The sixth redistribution pattern RP6 may have a via portion VP and a pad portion PP. A third conductive pad 31 may be disposed on the pad portion PP of the sixth redistribution pattern RP6. Each of the fourth to sixth redistribution patterns RP4 to RP6 may include copper. The third conductive pad 31 may include nickel.

The second sub-semiconductor package PK2 includes a second package substrate SB, a semiconductor device CH mounted thereon, a third mold layer MD3 on and/or covering or overlapping the second package substrate SH and the semiconductor device CH, a fourth mold layer MD4, a second heat spreader HS2, a second capping layer CPL2, and a second thermal interface material layer TM2.

The second thermal interface material layer TM2 is disposed on the semiconductor device CH. The second heat spreader HS2 is disposed on the second thermal interface material layer TM2. The second capping layer CPL2 is disposed on the second heat spreader HS2. The fourth mold layer MD4 is disposed on the side surface of the second heat spreader HS2. A side surface of the semiconductor device CH is covered with or overlapped by the third mold layer MD3. The third mold layer MD3, the fourth mold layer MD4, the second thermal interface material layer TM2, the second heat spreader HS2, and the second capping layer CPL2 may correspond to the first mold layer MD1, the second mold layer MD2, the first thermal interface material layer TM1, the first heat spreader HS1, and the first capping layer CPL1, respectively.

The semiconductor device CH may be electrically connected to the second package substrate SB by, for example, a wiring 360. The semiconductor device CH may be a single semiconductor die or a semiconductor chip, or a semiconductor package including a plurality of semiconductor dies of the same or different types. The semiconductor device CH may be at least one selected from an image sensor chip (e.g., a CMOS imaging sensor (CIS)), a memory chip (e.g., FLASH memory, DRAM, SRAM, EEPROM, PRAM, MRAM, ReRAM, high bandwidth memory (HBM), or hybrid memory cubic (HMC)), a microelectromechanical system (MEMS) device, or an application-specific integrated circuit (ASIC) chip.

The wiring 360 may include copper or gold. The second package board SB may be, for example, a double-sided or multi-layer printed circuit board. The second package substrate SB includes an upper substrate pad 380 disposed on the upper surface and a lower substrate pad 382 disposed on the lower surface. Internal wiring (not shown) may be disposed in the second package substrate SB to connect the upper substrate pad 380 and the lower substrate pad 382. The upper substrate pad 380 and the lower substrate pad 382 may include at least one of gold, copper, aluminum, and nickel.

The first sub-semiconductor package PK1 and the second sub-semiconductor package PK2 may be connected by a second internal connection member 260. The second internal connection member 260 connects the lower substrate pad 382 and the third conductive pad 31. A width of the third conductive pad 31 may be narrower or less than a width of the lower substrate pad 382. A width of the pad portion PP of the sixth redistribution pattern RP6 may be narrower or less than the width of the lower substrate pad 382.

The semiconductor package according to the present disclosure may include the heat spreader adjacent to the upper surface of the chip structure, and thus the heat generated from the chip structure may be effectively dissipated to the outside. Additionally, the second filler particles included in the second mold layer have the thermal conductivity greater than that of the first filler particles included in the first mold layer, and thus the heat generated from the chip structure may be effectively dissipated to the outside. This may prevent or inhibit the operational errors in the semiconductor package.

Additionally, as the upper surface of the chip structure is covered by or overlapped with the heat spreader and is not exposed to the outside, the chip structure may be protected or inhibited from the external shock. The portion of the second mold layer may be inserted into the groove of the heat spreader. As a result, it is difficult for the heat spreader to be separated from the second mold layer. This may prevent or inhibit the interfacial separation therebetween. Accordingly, the reliability of the semiconductor package may be improved.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims. The embodiments of FIGS. 1 through 15 can be combined with each other.

What is claimed is:

1. A semiconductor package comprising:
a package substrate;
a chip structure on the package substrate;
a first mold layer on side surfaces of the chip structure and an upper surface of the package substrate;
a heat spreader on the chip structure; and
a second mold layer on a side surface of the heat spreader and an upper surface of the first mold layer,
wherein the side surface of the heat spreader comprises at least one groove.

2. The semiconductor package of claim 1, wherein:
the heat spreader comprises a first portion and a second portion on the first portion,
the first portion has a first width,
a lower surface of the second portion has a second width that is less than the first width, and
an upper surface of the second portion has a third width that is greater than the second width.

3. The semiconductor package of claim 1, wherein:
the heat spreader comprises a first portion and a second portion on the first portion,
each of the first portion and the second portion comprises an upper surface and a lower surface,
the at least one groove is between the upper surface of the first portion and the lower surface of the second portion, and
a width of the upper surface of the second portion is greater than a width of the lower surface of the second portion.

4. The semiconductor package of claim 1, further comprising a capping layer on the heat spreader, wherein:
the heat spreader comprises copper, and
the capping layer comprises at least one of steel use stainless (SUS) or titanium.

5. The semiconductor package of claim 4, wherein:
the second mold layer is on a side surface of the capping layer, and
an upper surface of the capping layer is coplanar with an upper surface of the second mold layer.

6. The semiconductor package of claim 1, further comprising a thermal interface material layer between the chip structure and the heat spreader, wherein an upper surface of the thermal interface material layer is coplanar with the upper surface of the first mold layer.

7. The semiconductor package of claim 1, wherein:
the first mold layer comprises a first resin layer and first filler particles in the first resin layer,
the second mold layer comprises a second resin layer and second filler particles in the second resin layer, and
a thermal conductivity of the second filler particles is greater than a thermal conductivity of the first filler particles.

8. The semiconductor package of claim 7, wherein:
the first filler particles comprise silica, and
the second filler particles comprise at least one of aluminum, silver, tin, tungsten, copper, or titanium.

9. The semiconductor package of claim 1, wherein a portion of the second mold layer is between a lower surface of the heat spreader and the first mold layer.

10. The semiconductor package of claim 1, wherein:
a lower surface of the heat spreader has a first level relative to an upper surface of the package substrate, and
a lower surface of the second mold layer has a second level relative to the upper surface of the package substrate that is equal to or lower than the first level.

11. The semiconductor package of claim 1, wherein:
the first mold layer has a first thickness, and
the second mold layer has a second thickness that is less than the first thickness.

12. The semiconductor package of claim 11, wherein the second thickness is about 1/10 to ¼ of a total thickness of the first thickness and the second thickness.

13. A semiconductor package comprising:
a package substrate;
a chip structure on the package substrate;
a first mold layer on a side surface of the chip structure and an upper surface of the package substrate;
a heat spreader on the chip structure; and
a second mold layer on a side surface of the heat spreader and an upper surface of the first mold layer,
wherein the first mold layer comprises a first resin layer and first filler particles in the first resin layer,
wherein the second mold layer comprises a second resin layer and second filler particles in the second resin layer, and
wherein a thermal conductivity of the second filler particles is greater than a thermal conductivity of the first filler particles.

14. The semiconductor package of claim 13, wherein the side surface of the heat spreader comprises at least one groove.

15. The semiconductor package of claim 14, wherein:
the heat spreader comprises a first portion and a second portion on the first portion,
each of the first portion and the second portion has an upper surface and a lower surface,
the at least one groove is between the upper surface of the first portion and the lower surface of the second portion, and
a width of the upper surface of the second portion is greater than a width of the lower surface of the second portion.

16. The semiconductor package of claim 13, further comprising a thermal interface material layer between the chip structure and the heat spreader, wherein an upper surface of the thermal interface material layer is coplanar with the upper surface of the first mold layer.

17. The semiconductor package of claim 13, further comprising a thermal interface material layer between the chip structure and the heat spreader, wherein the second mold layer is on a side surface of the thermal interface material layer.

18. A semiconductor package comprising:
a package substrate;
external connection terminals on a lower surface of the package substrate;
a chip structure on the package substrate;
a first mold layer on a side surface of the chip structure and an upper surface of the package substrate;
a heat spreader on the chip structure;
a thermal interface material layer between the chip structure and the heat spreader;
a second mold layer on a side surface of the heat spreader and an upper surface of the first mold layer; and
a capping layer on the heat spreader,
wherein the side surface of the heat spreader comprises at least one groove,
wherein a lower surface of the heat spreader has a first level relative to an upper surface of the package substrate, and
wherein a lower surface of the second mold layer has a second level relative to the upper surface of the package substrate that is equal to or lower than the first level.

19. The semiconductor package of claim 18, wherein:
the first mold layer comprises a first resin layer and first filler particles in the first resin layer,
the second mold layer comprises a second resin layer and second filler particles in the second resin layer, and
a thermal conductivity of the second filler particles is greater than a thermal conductivity of the first filler particles.

20. The semiconductor package of claim 18, wherein a portion of the second mold layer is between the lower surface of the heat spreader and the first mold layer.
